(19) United States
(12) Patent Application Publication
(10) Pub. No.: US 2011/0063816 A1
(43) Pub. Date: Mar. 17, 2011

(54) Wired circuit board, connection structure thereof, and connection method therefor

(75) Inventors: Hiroyuki Tanabe, Osaka (JP); Toshiki Naito, Osaka (JP)

(73) Assignee: Nitto Denko Corporation, Osaka (JP)

(21) Appl. No.: 12/805,939

(22) Filed: Aug. 25, 2010

(30) Foreign Application Priority Data
Sep. 17, 2009 (JP) 2009-215977

(51) Int. Cl. H05K 1/11; H05K 3/36

(52) U.S. Cl. 361/803; 29/830

(57) ABSTRACT

A wired circuit board includes a first wired circuit board provided with a first conductive pattern which has first terminals comprising placement surfaces for placing a meltable metal and first wires continuous with the first terminals; and a second wired circuit board provided with a second conductive pattern which has second terminals connected with the first terminals through the meltable metal and second wires continuous with the second terminals. The first wired circuit board and the second wired circuit board are arranged so that a first plane containing the first terminals and a second plane containing the second terminals are intersected with each other, and the placement surfaces are zoned so as to gradually widen toward the second terminals.

### CROSS REFERENCE TO RELATED APPLICATION

The present application claims priority from Japanese Patent Application No. 2009-215977 filed on Sep. 17, 2009, the content of which is hereby incorporated by reference in its entirety.

### BACKGROUND OF THE INVENTION

1. Field of the Invention

The present invention relates to a wired circuit board, a connection structure thereof, and a connection method therefor. More particularly, the present invention relates to a wired circuit board suitably used for connection of a suspension board with circuit and a relay flexible wired circuit board, a connection structure thereof, and a connection method therefor.

2. Description of Related Art

Conventionally, a suspension board with circuit mounted on a hard disk drive has been connected to a control circuit board through a relay flexible wired circuit board, and relay terminals of the suspension board with circuit and suspension terminals of the relay flexible wired circuit board have been connected via bumps.

In the connection described above, the suspension board with circuit and the relay flexible wired circuit board have been known to be arranged so that their planes are orthogonal to each other.

There has been proposed, for example, that in the above-mentioned construction and arrangement, a cutout cut in a semicircular arc shape in plan view is formed in the center of each relay terminal (cf. Japanese Unexamined Patent Publication No. 2006-165268).

In Japanese Unexamined Patent Publication No. 2006-165268, a hemispherical bump is formed in a surface of each suspension terminal, and the bumps are then fitted into the cutouts of the relay terminals, thereby achieving reduction in size.

### SUMMARY OF THE INVENTION

However, the relay terminals of Japanese Unexamined Patent Publication No. 2006-165268 is required to have cutouts formed, which is time-consuming and troublesome. Therefore, the manufacturing process may become complicated.

Further, the contact between the bumps and the cutouts becomes insufficient, which may result in insufficient connection between the relay terminals and the suspension terminals.

It is an object of the present invention to provide a wired circuit board that can allow simple and secure connection between a first terminal and a second terminal even if a first wired circuit board and a second wired circuit board are arranged so that a first plane and a second plane are intersected with each other.

The wired circuit board of the present invention includes a first wired circuit board provided with a first conductive pattern which has a first terminal comprising placement surface for placing a meltable metal and a first wire continuous with the first terminal; and a second wired circuit board provided with a second conductive pattern which has a second terminal connected with the first terminal through the meltable metal and a second wire continuous with the second terminal, in which the first wired circuit board and the second wired circuit board are arranged so that a first plane containing the first terminal and a second plane containing the second terminal are intersected with each other, and the placement surface is zoned so as to gradually widen toward the second terminal.

In the wired circuit board of the present invention, it is preferable that the first wired circuit board includes an insulating cover layer which covers the first wire and exposes the first terminal, and the first terminal is formed so as to gradually widen toward the second terminal, whereby the placement surface is zoned so as to gradually widen toward the second terminal.

In the wired circuit board of the present invention, it is preferable that the first wired circuit board includes an insulating cover layer which covers the first wire and partially exposes the first terminal, and the placement surface is zoned so as to gradually widen toward the second terminal by being exposed from the insulating cover layer so as to gradually widen toward the second terminal.

In the wired circuit board of the present invention, it is preferable that the placement surface is zoned in a generally trapezoidal shape when projected in a thickness direction of the first wired circuit board.

In the wired circuit board of the present invention, it is preferable that the placement surface is zoned in a generally triangular shape when projected in a thickness direction of the first wired circuit board.

The connection structure of the wired circuit boards of the present invention include a first wired circuit board provided with a first conductive pattern which has a first terminal comprising a placement surface for placing a meltable metal and a first wire continuous with the first terminal; and a second wired circuit board provided with a second conductive pattern which has a second terminal connected with the first terminal through the meltable metal and a second wire continuous with the second terminal, in which the first wired circuit board and the second wired circuit board are arranged so that a first plane containing the first terminal and a second plane containing the second terminal are intersected with each other, the placement surface is zoned so as to gradually widen toward the second terminal, and the first terminal and the second terminals connected through the meltable metal.

The method for connecting the wired circuit boards of the present invention includes the steps of preparing a first wired circuit board provided with a first conductive pattern which has a first terminal including a placement surface zoned so as to gradually widen outward and a first wire continuous with the first terminal; preparing a second wired circuit board provided with a second conductive pattern which has a second terminal and a second wire continuous with the second terminal; placing a meltable metal on the placement surface of the first terminal; arranging the first wired circuit board and the second wired circuit board so that the first plane including the first terminal and the second plane including the second terminal are intersected with each other; and connecting the first terminal and the second terminal through the meltable metal by melting the meltable metal.

In the wired circuit board of the present invention, the placement surface of the first terminal is zoned so as to gradually widen toward the second terminal.

Therefore, in the method for connecting the wired circuit board of the present invention, when the meltable metal is placed on the placement surface and then melted, the meltable metal is unevenly distributed toward the second terminal. That is, the meltable metal is formed to be gradually thicker toward the second terminal.

The first wired circuit board and the second wired circuit board are arranged so that the first plane and the second plane are intersected with each other, thereby allowing the second terminal to contact over a wide contact area with a thickened portion of the meltable metal.

Therefore, the connection between the first terminal and the second terminal through the meltable metal, and further, the connection between the first wired circuit board and the second wired circuit board can be secured.

Since the first terminal is formed with simple construction, even if the first wired circuit board and the second wired circuit board are arranged so that the first plane and the second plane are intersected with each other, the first terminal and the second terminal can be easily connected.

Furthermore, since the meltable metal is formed to be gradually thicker toward the second terminal, the meltable metal can contact the second terminal even if the amount of the metal used for formation of the meltable metal is reduced by such thickened amount. Therefore, cost can be reduced.

### BRIEF DESCRIPTION OF THE DRAWINGS

FIG. 1 is a plan view of a relay flexible wiring circuit board provided in one embodiment of a wired circuit board according to the present invention;

FIG. 2 is a sectional view of a suspension terminal taken along the line A-A shown in FIG. 1;

FIG. 3 is a plan view of the suspension terminal shown in FIG. 2;

FIG. 4 is a plan view of a suspension board with circuit provided in one embodiment of the wired circuit board according to the present invention;

FIG. 5 is a sectional view of a relay terminal taken along the line B-B shown in FIG. 4;

FIG. 6 is a perspective view for explaining one embodiment of a method for connecting a wired circuit board according to the present invention, showing the step of arranging a relay flexible wired circuit board and a suspension board with circuit so that a first plane and a second plane are orthogonal to each other;

FIG. 7 is sectional views of the suspension terminal and the relay terminal shown in FIG. 6;

FIG. 8 shows the step of connecting between a suspension terminal and a relay terminal;

FIG. 9 is a perspective view of a suspension terminal as another embodiment (an embodiment formed in a generally trapezoidal shape having a generally right angle) of the wired circuit board according to the present invention;

FIG. 10 is a perspective view of a suspension terminal as another embodiment (an embodiment formed in a generally trapezoidal shape with both widthwise opposite edges thereof being curved) of the wired circuit board according to the present invention;

FIG. 11 is a perspective view of a suspension terminal as another embodiment (an embodiment formed in a generally hexagonal shape) of the wired circuit board according to the present invention;

FIG. 12 is a perspective view of a suspension terminal as another embodiment (an embodiment formed in a generally hexagonal shape) of the wired circuit board according to the present invention;

FIG. 13 is a perspective view of another embodiment (an embodiment in which a placement surface is exposed in a generally trapezoidal shape from a cutout) of the wired circuit board according to the present invention; and

FIG. 14 is a perspective view of another embodiment (an embodiment in which a placement surface is exposed in a generally triangular shape from a cutout) of the wired circuit board according to the present invention.

### DETAILED DESCRIPTION OF PREFERRED EMBODIMENTS

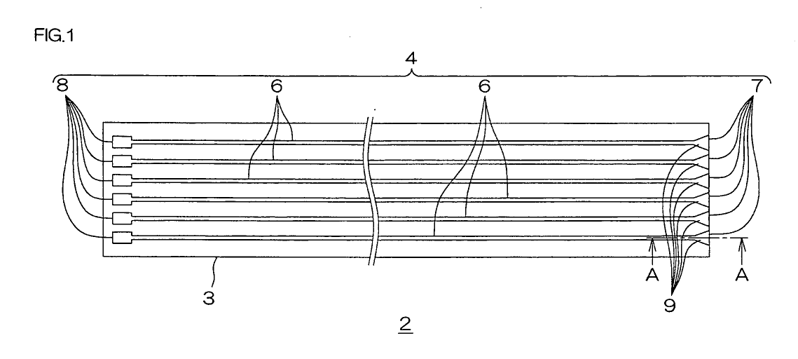

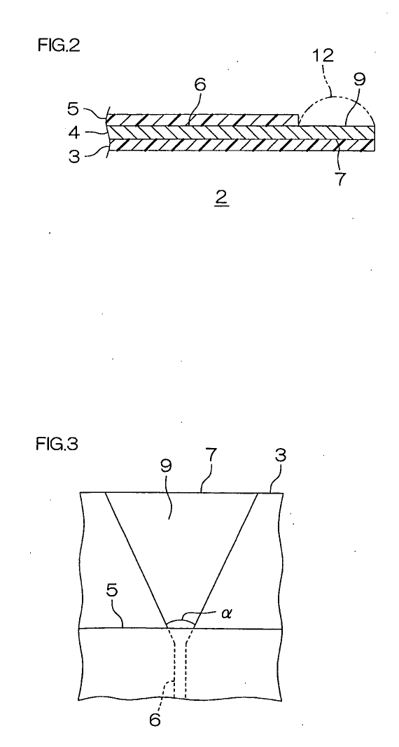

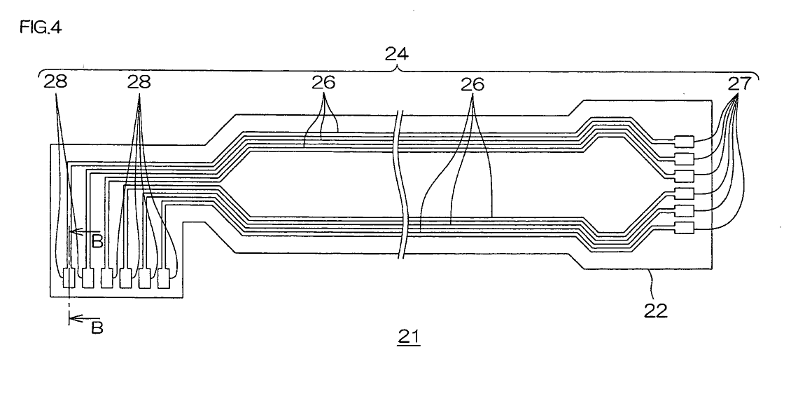

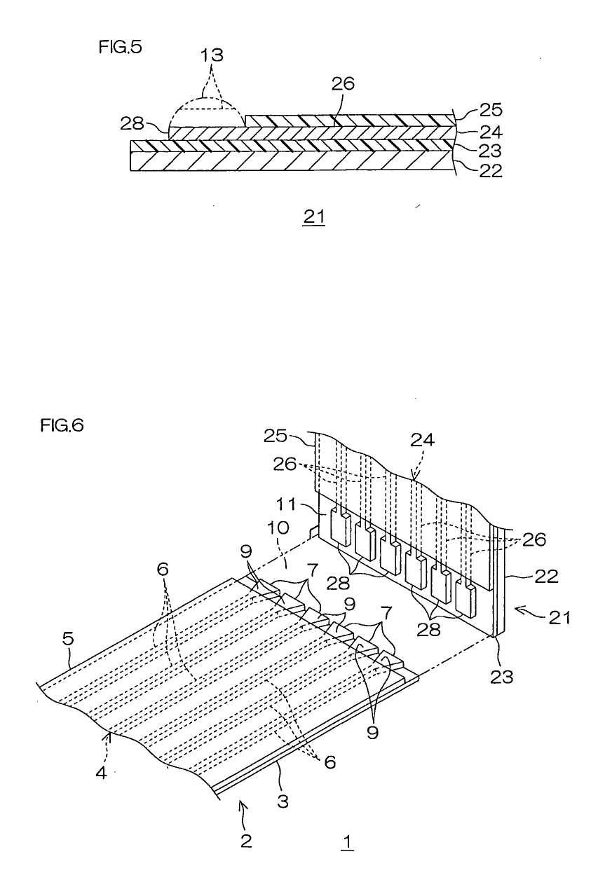

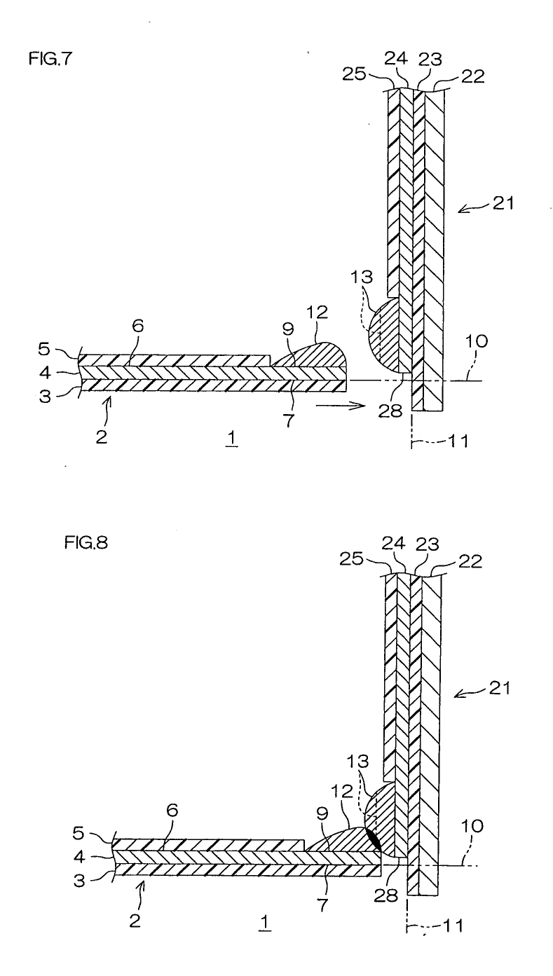

FIG. 1 is a plan view of a relay flexible wiring circuit board provided in one embodiment of a wired circuit board according to the present invention; FIG. 2 is a sectional view of a suspension terminal taken along the line A-A shown in FIG. 1; FIG. 3 is a plan view of the suspension terminal shown in FIG. 2; FIG. 4 is a plan view of a suspension board with circuit provided in one embodiment of the wired circuit board according to the present invention; FIG. 5 is a sectional view of a relay terminal taken along the line B-B shown in FIG. 4; FIG. 6 is a perspective view for explaining one embodiment of a method for connecting a wired circuit board according to the present invention, showing the step of arranging a relay flexible wired circuit board and a suspension board with circuit so that a first plane and a second plane are orthogonal to each other; FIG. 7 is sectional views of the suspension terminal and the relay (terminal shown in FIG. 6; and FIG. 8 shows the step of connecting between a suspension terminal and a relay terminal.

To clearly illustrate a relative position of a first conductive pattern 4, a first insulating cover layer 5 described later is omitted in FIG. 1. In addition to this, a second insulating base layer 23 and a second insulating cover layer 25 to be described later are also omitted in FIG. 4 in order to clarify a relative configuration of a second conductive pattern 24 to be described later.

In FIG. 6, the wired circuit board 1 includes a relay flexible wired circuit board 2 as a first wired circuit board, and a suspension board with circuit 21 as a second wired circuit board.

As shown in FIG. 1, the relay flexible wired circuit board 2 transmits a read/write signal between external boards (not shown) such as a magnetic head (not shown) and a control device, and is integrally formed with a first conductive pattern 4 for connecting with the suspension board with circuit 21.

As shown in FIG. 2, the relay flexible wired circuit board 2 includes a first insulating base layer 3, a first conductive pattern 4 formed on the first insulating base layer 3, and a first insulating cover layer 5 formed on the first insulating base layer 3 so as to cover the first conductive pattern 4.

As shown in FIG. 1, the first insulating base layer 3 has an outer shape of the relay flexible wired circuit board 2, and is formed of a film having a generally rectangular strip-like shape in plan view extending in a lengthwise direction.

The first conductive pattern 4 integrally has a suspension terminal 7 as a first terminal, an external terminal 8, and a first wire 6 electrically connected between the suspension terminal 7 and the external terminal 8.

The suspension terminal 7 is arranged in the front end portion (one lengthwise end portion) of the relay flexible wired circuit board 2, and a plurality (six pieces) of the suspension terminals 7 are arranged in parallel at spaced intervals to each other along a widthwise direction (a direction orthogonal to the lengthwise direction).

Specifically, as shown in FIG. 3, each of the suspension terminals 7 is formed in a generally trapezoidal shape (a trapezoidal land) in plan view (when projected in a thickness direction) gradually widening toward the front side.

The leading edges of the suspension terminals 7 are arranged in the same position as the leading edge of the first insulating base layer 3 as viewed in plane and are flush with the leading edge thereof in the thickness direction.

As shown in FIG. 1, the external terminal 8 is arranged in the rear end portion (the other lengthwise end portion) of the relay flexible wired circuit board 2, and a plurality (six pieces) of the external terminals 8 are arranged in parallel at spaced intervals to each other along the widthwise direction.

Specifically, each of the external terminals 8 is formed in a generally rectangular shape (a square land) in plan view extending in the lengthwise direction. The trailing edges of the suspension terminals 7 are arranged at spaced intervals to the trailing edge of the first insulating base layer 3 and are parallel thereto.

The first wire 6 extends in the lengthwise direction and a plurality (six pieces) of the first wires 6 are arranged in parallel at spaced intervals to each other along the widthwise direction. The first wires 6 are formed so that their front ends are continuous with the trailing edges of the suspension terminals 7 and that their rear ends are continuous with the leading edges of the external terminals 8.

As shown in FIGS. 2, 3, and 6, the first insulating cover layer 5 is formed of a film having a generally rectangular strip-like shape in plan view extending in the lengthwise direction. The first insulating cover layer 5 is formed on the first insulating base layer 3 in a pattern which covers the first wires 6 and exposes the suspension terminals 7 and the external terminals 8.

Specifically, in the widthwise direction, the first insulating cover layer 5 covers the upper surface of the first insulating base layer 3, and the upper surfaces and both widthwise side surfaces of the first wires 6: Further, in the lengthwise direction, the first insulating cover layer 5 is formed slightly shorter than the first insulating base layer 3, and exposes the suspension terminals 7 and the external terminals 8.

That is, the front end portion of the first insulating cover layer 5 exposes the lengthwise centers and the front end portions of the plurality of suspension terminals 7, and covers the rear end portions thereof. The leading edge of the first insulating cover layer 5 is linearly formed along the widthwise direction, and is arranged on the rear side at a region where the lengthwise centers and the front end portions of the suspension terminals 7 are arranged, away from the leading edge of the first insulating base layer 3.

Although not shown in FIG. 6, the rear end portion of the first insulating cover layer 5 exposes the lengthwise centers and the rear end portions of the plurality of external terminals 8, and covers the front end portions thereof. The trailing edge of the first insulating cover layer 5 is linearly formed along the widthwise direction, and is arranged on the front side at a region where the external terminals 8 are arranged, away from the trailing edge of the first insulating base layer 3.

In the relay flexible wired circuit board 2, each suspension terminal 7 has a placement surface 9 for placing a first bump 12 as a meltable metal.

As shown in FIG. 3, the placement surfaces 9 serve as the surfaces of the suspension terminals 7 exposed from the first insulating cover layer 5. In other words, the placement surfaces 9 serve as the surfaces of the lengthwise intermediate portions and the front end portions of the suspension terminals 7. Thus, each of the placement surfaces 9 is zoned in a generally trapezoidal shape in plan view (when projected in the thickness direction) gradually widening toward the front side.

In order to obtain the relay flexible wired circuit board 2, a first insulating base layer 3 is first prepared.

The insulating materials that may be used for forming the first insulating base layer 3 include, for example, synthetic resins such as polyimide resin, polyamide imide resin, acrylic resin, polyether nitrile resin, polyether sulfone resin, polyethylene terephthalate resin, polyethylene naphthalate resin, and polyvinyl chloride resin. Of these resins, polyimide resin is preferably used.

The first insulating base layer 3 is formed in the following manner. For example, a varnish of photosensitive resin (photosensitive polyamic acid resin) is coated over the entire upper surface of a support plate which is not shown. Thereafter, the coated varnish is exposed to light via a photomask and then developed. Subsequently, the resulting product is heated to be dried and cured, to thereby forming a first insulating base layer 3.

The first insulating base layer 3 thus formed has a thickness in the range of, for example, 5 to 20 μm, or preferably 7 to 15 μm.

Then, a first conductive pattern 4 is formed on the first insulating base layer 3.

The conductive materials that may be used for forming the first conductive pattern 4 include, for example, copper, nickel, gold, or alloys thereof. Of these, copper is preferably used.

The first conductive pattern 4 is formed into the above-mentioned pattern by a known patterning method, such as an additive method or a subtractive method.

The first conductive pattern 4 thus formed has a thickness in the range of, for example, 3 to 50 μm, or preferably 5 to 20 μm.

Each of the first wires 6 has a width (length in widthwise direction) in the range of, for example, 2 to 200 μm, or preferably 5 to 100 μm. The spacing (spacing in widthwise direction) between each of the first wires 6 ranges, for example, from 2 to 200 μm, or preferably from 5 to 100 μm.

The suspension terminals 7 and the external terminals 8 each have a length (length in lengthwise direction) in the range of, for example, 50 to 2000 μm, or preferably 150 to 1000 μm.

The trailing edge of the suspension terminal 7 has substantially the same width as the first wire 6. The leading edge of the suspension terminal 7 has a larger width than the trailing edge thereof, and specifically, has a width of, for example, 125 μm or more, preferably 150 μm or more, or more preferably 250 μm or more, and usually 1000 μm or less. The spacing between the suspension terminals 7 ranges, for example, from 20 to 100 μm, or preferably from 30 to 50 μm at the trailing edge, and from 2 to 20 μm, or preferably from 5 to 10 μm at the leading edge.

The trailing edge of the placement surface 9 has a width of, for example, more than 50 μm, or preferably 100 μm, and less than 250 μm, or preferably less than 150 μm.

In each of the suspension terminals 7, an angle α which is formed between both widthwise opposite edges thereof ranges, for example, from 20 to 120 degrees, or preferably from 40 to 90 degrees.

The width of each of the external terminals 8 and the spacing between them range, for example, from 20 to 800 μm, or preferably from 30 to 500 μm.

Next, a first insulating cover layer 5 is formed on the first insulating base layer 3 so as to cover the first conductive pattern 4.

The insulating materials that may be used for forming the first insulating cover layer 5 include the same materials as those used for forming the first insulating base layer 3 as described above.

The first insulating cover layer 5 is formed in the following manner. For example, a varnish of photosensitive resin (photosensitive polyamic acid resin) is coated over the upper surfaces of the first insulating base layer 3 and the first conductive pattern 4. Thereafter, the coated varnish is exposed to light via a photomask and then developed. Subsequently, the resulting product is heated to be dried and cured, to thereby forming a first insulating cover layer 5.

The first insulating cover layer 5 thus formed has a thickness in the range of, for example, 5 to 20 μm, or preferably 7 to 15 μm.

Thereafter, the support plate is removed by peeling or etching.

Thus, the relay flexible wired circuit board 2 is obtained.

As shown in FIG. 4, the suspension board with circuit 21 is mounted on a hard disk drive, with a magnetic head (not shown) being mounted thereon, and is integrally formed with a second conductive pattern 24 for connecting the magnetic head and the relay flexible wired circuit board 2 mentioned above.

As shown in FIG. 5, the suspension board with circuit 21 includes a metal supporting board 22, a second insulating base layer 23 formed on the metal supporting board 22, a second conductive pattern 24 formed on the second insulating base layer 23, and a second insulating cover layer 25 formed on the second insulating base layer 23 so as to cover the second conductive pattern 24.

As shown in FIG. 4, the metal supporting board 22 has an outer shape of the suspension board with circuit 21, and is formed of a thin plate having a generally rectangular shape in plan view extending in a lengthwise direction. Specifically, the metal supporting board 22 is formed so that its front end portion (one lengthwise end portion of the suspension board with circuit 21) expands toward both sides in a widthwise direction (a direction orthogonal to the lengthwise direction) and that its rear end portion (the other lengthwise end portion thereof) expands toward one widthwise side.

As shown in FIG. 5, the second insulating base layer 23 is formed on the upper surface of the metal supporting board 22 in a pattern corresponding to a portion where the second conductive pattern 24 is formed.

As shown in FIG. 4, the second conductive pattern 24 integrally has a head terminal 27, a relay terminal 28 as a second terminal, and a second wire 26 electrically connected between the head terminal 27 and the relay terminal 28.

The head terminal 27 is arranged in the front end portion of the suspension board with circuit 21, and a plurality (six pieces) of the head terminals 27 are arranged in parallel at spaced intervals to each other along the widthwise direction.

Specifically, each of the head terminals 27 is formed in a generally rectangular shape (a square land) in plan view extending in the lengthwise direction. The leading edges of the head terminals 27 are arranged at spaced intervals to the leading edge of the metal supporting board 22 and are parallel thereto.

The relay terminal 28 is arranged in one widthwise end of the rear end portion of the suspension board with circuit 21, and is arranged along one widthwise edge of the rear end portion of the suspension board with circuit 21.

Specifically, a plurality (six pieces) of the relay terminals 28 are arranged in parallel at spaced intervals to each other along the lengthwise direction, and each formed in a generally rectangular shape (a square land) in plan view extending in the widthwise direction. The trailing edges (one widthwise edges) of the relay terminals 28 are arranged at spaced intervals to one widthwise edge of the metal supporting board 22.

As shown in FIG. 4, the second wire 26 extends in the lengthwise direction and a plurality (six pieces) of the second wires 26 are arranged in parallel at spaced intervals to each other along the widthwise direction. More specifically, the second wires 26 are formed so that their front ends are continuous with the trailing edges of the head terminals 27 and that in the rear end portion of the suspension board with circuit 21, their rear ends are bent toward one widthwise side and are then continuous with the trailing edges (the other widthwise edges) of the relay terminals 28.

As shown in FIGS. 5 and 6, the second insulating cover layer 25 is formed of a film having a generally rectangular strip-like shape in plan view extending in the lengthwise direction. The second insulating cover layer 25 is formed on the second insulating base layer 23 in a pattern which covers the second wires 26 and exposes the head terminals 27 and the relay terminals 28.

Specifically, partway in the lengthwise direction, the second insulating cover layer 25 covers the upper surface (surface) of the second insulating base layer 23, and the upper surfaces (surfaces) and both widthwise side surfaces of the second wires 26. Although not shown in FIG. 6, the front end portion of the second insulating cover layer 25 exposes all the head terminals 27. The leading edge of the second insulating cover layer 25 is linearly formed along the widthwise direction, and is arranged on the rear side at a region where the head terminals 27 are arranged, away from the leading edge of the metal supporting board 22.

As shown in FIG. 6, the rear end portion of the second insulating cover layer 25 exposes all the relay terminals 28. One widthwise edge of the rear end portion of the second insulating cover layer 25 is linearly formed along the lengthwise direction, and is arranged on the other widthwise side at a region where the relay terminals 28 are arranged, away from one widthwise edge of the rear end portion of the metal supporting board 22.

In order to obtain this suspension board with circuit 21, as shown in FIG. 5, the metal supporting board 22 is first prepared.

The metal materials that may be used for forming the metal supporting board 22 includes, for example, stainless steel, 42-alloy, aluminum, copper-beryllium, and phosphor bronze. Of these, a stainless steel is preferably used.

The metal supporting board 22 has a thickness in the range of, for example, 15 to 50 μm, or preferably 20 to 30 μm.

Next, a second insulating base layer 23 is formed on the metal supporting board 22.

The insulating materials that may be used for forming the second insulating base layer 23 include the same materials as those used for forming the first insulating base layer 3 as described above.

The second insulating base layer 23 is formed in the following manner. For example, a varnish of photosensitive resin (photosensitive polyamic acid resin) is coated over the entire upper surface of the metal supporting board 22. Thereafter, the coated varnish is exposed to light via a photomask and then developed. Subsequently, the resulting product is heated to be dried and cured, to thereby forming a second insulating base layer 23.

The second insulating base layer 23 thus formed has a thickness in the range of, for example, 5 to 20 μm, or preferably 7 to 15 μm.

Next, a second conductive pattern 24 is formed on the second insulating base layer 23.

The conductive materials that may be used for forming the second conductive pattern 24 include the same materials as those used for forming the first conductive pattern 4 as described above.

The second conductive pattern 24 is formed into the above-mentioned pattern by a known patterning method, such as an additive method or a subtractive method.

The second conductive pattern 24 thus formed has a thickness in the range of, for example, 3 to 50 μm, or preferably 5 to 20 μm.

Each of the second wires 26 has a width in the range of, for example, 2 to 100 μm, or preferably 5 to 50 μm. The spacing between each of the second wires 26 is in the range of, for example, 2 to 100 μm, or preferably 5 to 50 μm.

Each of the length (length in lengthwise direction) of the head terminal 27 and the length (length in widthwise direction) of the relay terminal 28 is in the range of, for example, 200 to 5000 μm, or preferably 500 to 2000 μm.

Each of the width (length in widthwise direction) of the head terminal 27 and the width (length in lengthwise direction) of the relay terminal 28 each is in the range of, for example, 20 to 800 μm, or preferably 30 to 500 μm.

Each of the spacing (spacing in lengthwise direction) between the head terminals 27 and the spacing (spacing in widthwise direction) between the relay terminals 28 is in the range of, for example, 20 to 800 μm, or preferably 30 to 500 μm.

Next, a second insulating cover layer 25 is formed on the second insulating base layer 23 so as to cover the second conductive pattern 24.

The insulating materials that may be used for forming the second insulating cover layer 25 include the same materials as those used for forming the first insulating base layer 3 as described above.

The second insulating cover layer 25 is formed in the following manner. For example, a varnish of photosensitive resin (photosensitive polyamic acid resin) is coated over the upper surfaces (surfaces) of the second insulating base layer 23 and the second conductive pattern 24. Thereafter, the coated varnish is exposed to light via a photomask and then developed. Subsequently, the resulting product is heated to be dried and cured, to thereby forming a second insulating cover layer 25.

The second insulating cover layer 25 thus formed has a thickness in the range of, for example, 5 to 20 μm, or preferably 7 to 15 μm.

Thus, the suspension board with circuit 21 is obtained.

Next, a method for connecting between the relay flexible wired circuit board 2 and the suspension board with circuit 21 is described with reference to FIGS. 2, and 5 to 8.

First, in this method, as shown in FIGS. 2 and 5, the relay flexible wired circuit board 2 and the suspension board with circuit 21 described above are separately prepared.

Subsequently, in this method, as shown in phantom line in FIG. 2, first bumps 12 are placed on the placement surfaces 9 of the suspension terminals 7 of the relay flexible wired circuit board 2.

The materials that may be used for the first bumps 12 include, for example, alloys (solder alloy) made of at least two or more kinds selected from tin, indium, silver, copper, zinc, lead, gold, antimony, and bismuth. Of these, a tin alloy containing tin is preferably used. A cream solder containing the above-mentioned solder alloy can also be used.

The first bumps 12 are placed by a printing method such as a screen printing method of printing cream solder at a temperature lower than the melt temperature of the first bump 12.

The first bumps 12 thus placed are formed into a generally semicircular or semi-elliptical cross sectional shape.

Each of the first bumps 12 has a height of, for example, 20 to 500 μm, and the bottom surface thereof has a diameter (maximum length) of, for example, 40 to 1000 μm.

As shown in phantom line in FIG. 5, second bumps 13 are placed on the surfaces of the relay terminals 28 in the suspension board with circuit 21.

The materials used for the second bumps 13 include the same materials as those used for the first bumps 12 as described above. Besides, the placement method of the second bumps 13 is the same as that used for the first bumps 12 as described above. As shown in phantom line in FIG. 5, the second bumps 13 are formed into a generally semicircular or semi-elliptical cross sectional shape. The size of the second bump 13 is the same as that of the first bump 12.

Next, in this method, as shown in FIGS. 6 and 7, the relay flexible wired circuit board 2 and the suspension board with circuit 21 are arranged so that a first plane 10 including the suspension terminals 7 and a second plane 11 including the relay terminals 28 are orthogonal to each other.

As shown in phantom line in FIGS. 6 and 7, the first plane 10 is a plane which spreads along the first conductive pattern 4 in the relay flexible wired circuit board 2.

Further, the second plane 11 is a plane which spreads along the second conductive pattern 24 in the suspension board with circuit 21.

Accordingly, the suspension board with circuit 21 is arranged in opposed relation to the front side of the relay flexible wired circuit board 2 so that the first plane 10 and the second plane 11 are orthogonal to each other. More particularly, the suspension board with circuit 21 is arranged at an angle of generally 90 degrees at spaced intervals to the relay flexible wired circuit board 2 on the front side of the relay flexible wired circuit board 2.

Thus, the first bump 12 and the second bump 13 are arranged in opposed relation to each other.

Next, in this method, the first bumps 12 placed on the placement surfaces 9 and the second bumps 13 placed on the surfaces of the relay terminals 28 are melted.

The first bumps 12 and the second bumps 13 are melted by heating the first bumps 12 and the second bumps 13 at a temperature higher than their melt temperature by a heating method such as laser (Xe lamp laser) irradiation or using a soldering iron. Preferably, the first bumps 12 and the second bumps 13 are heated by laser radiation.

Immediately after the heating (or at the same time of heating, i.e., while the first bumps 12 and the second bumps 13 are being melted), the first bumps 12 and the second bumps 13 are brought into contact with each other as shown in FIG. 8.

In order to bring the first bump 12 and the second bump 13 into contact with each other, the relay flexible wired circuit board 2 and the suspension hoard with circuit 21 are moved (slided) closer to each other as indicated by the arrow in FIG. 7. For example, the suspension terminals 7 of the relay flexible wired circuit board 2 are moved closer toward the relay terminals 28 of the suspension board with circuit 21 along the first plane 10.

Thus, the suspension terminals 7 and the relay terminals 28 are connected to each other through the first bumps 12 and the second bumps 13.

The external terminals 8 (see FIG. 1) are connected to terminals (not shown) of an external board by a known method, and the head terminals 27 (see FIG. 4) are connected to terminals (not shown) of a magnetic head by a known method.

In this wired circuit board 1, the placement surfaces 9 of the suspension terminals 7 are zoned so as to gradually widen toward the front side.

Therefore, in the connection between the relay flexible wired circuit board 2 and the suspension board with circuit 21 as described above, when the first bumps 12 are placed on the placement surfaces 9 and then melted, the first bumps 12 are unevenly distributed toward the front side, as shown in FIG. 7.

That is, each of the first bumps 12 is formed to be gradually thicker toward the front side. More specifically, each of the first bumps 12 is formed into a generally drop-shaped cross-section or a streamlined half-split shape having a gravity center on the front side.

Then, the relay flexible wired circuit board 2 and the suspension board with circuit 21 are arranged so that the first plane 10 and the second plane 11 are orthogonal to each other, whereby the second bumps 13 formed on the surfaces of the relay terminals 28 can contact over a wide contact area with thickened portions of the first bumps 12.

Therefore, the connection between the suspension terminals 7 and the relay terminals 28 through the first bumps 12 and the second bumps 13, and further, the connection between the relay flexible wired circuit board 2 and the suspension board with circuit 21 can be secured.

The suspension terminals 7 are formed with a simple construction each having a generally trapezoidal shape in plan view. Therefore, even if the relay flexible wired circuit board 2 and the suspension board with circuit 21 are arranged so that the first plane 10 and the second plane 11 are intersected with each other, the suspension terminals 7 and the relay terminals 28 can be easily connected.

Further, since the first bumps 12 placed on the placement surfaces 9 are formed to be gradually thicker toward the front side, the first bumps 12 can contact the relay terminals 28 even if the amount of the material used for formation of the first bumps 12 is reduced by such thickened amount. Therefore, cost can be reduced.

Furthermore, since the amount of the material used for the formation of the first bumps 12 is reduced, the first bumps 12 can be formed compactly. Therefore, a short circuit of adjacent suspension terminals 7 caused by a contact between the first bumps 12 in the widthwise direction can be prevented effectively.

In the relay flexible wired circuit board 2, since the leading edge of the first insulating cover layer 5 is linearly formed, the first insulating cover layer 5 can be formed with a simple construction.

In the above explanation, the upper surface of each second bump 13 is formed in a curved shape. However, for example, as indicated by dashed lines in FIGS. 5, 7, and 8, it may be formed into a smooth surface.

The upper surfaces (the smooth surfaces) of the second bumps 13 are formed in parallel to the second plane 11.

The smoothing surfaces of the second bumps 13 are formed in the following manner. After the second bumps 13 are placed on the relay terminals 28, before the second bumps 13 are located closer to the first bumps 12, the curved upper surfaces of the second bumps 13 are subjected to smoothing processing, for example, by pressing process (crushing work) using pressure. In this case, the melt-heating process of the second bumps 13 can be omitted.

In the above explanation, the second bumps 13 are formed on the surfaces of the relay terminals 28. However, for example, though not shown, the suspension terminals 7 and the relay terminals 28 may be connected through the first bumps 12, without forming the second bumps 13 on the surfaces of the relay terminals 28.

Thus, cost can be further reduced.

In the above explanation, the suspension terminals 7 and the relay terminals 28 are moved closer to each other immediately after the melting of the first bumps 12 and the second bumps 13. However, for example, though not shown, the suspension terminals 7 and the relay terminals 28 are preliminarily arranged closely to each other and the first bumps 12 and the second bumps 13 are then melted to be in contact with each other, so that the suspension terminals 7 and the relay terminals 28 can be connected with each other.

This method can eliminate the need for moving (sliding) of the relay flexible wired circuit board 2 closer to the suspension board with circuit 21 after the melting of the first bumps 12 and the second bumps 13. Therefore, the suspension terminals 7 and the relay terminals 28 can be more easily connected with each other.

In the above explanation, the first bumps 12 are placed by the printing method conducted at a temperature lower than the melt temperature of the first bumps 12. However, for example, the first humps 12 may be placed by a heat coating method of heating the first bumps 12 at a temperature higher than the melt temperature of the first bumps 12, such as flow.

In such case, each of the first bumps 12 thus placed is formed to already be gradually thicker toward the front side as shown in FIG. 7, and more specifically, formed in a generally drop-shaped cross-section or a streamlined half-split shape having a gravity center on the front side.

In other words, after the first bump 12 is placed on the placement surface 9, the shape of the first bump 12 before melting for connection between the suspension terminals 7 and the relay terminals 28 is substantially the same as that after the melting for the connection described above.

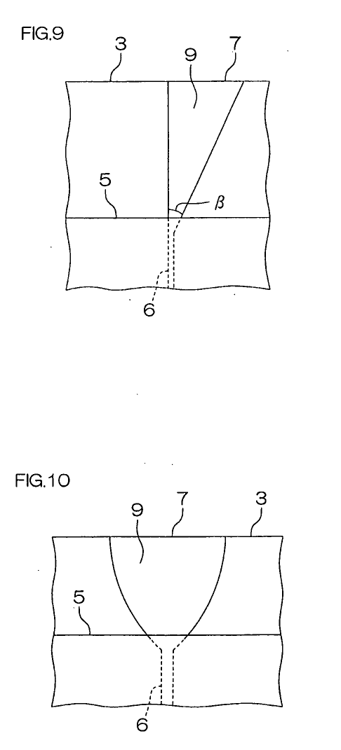

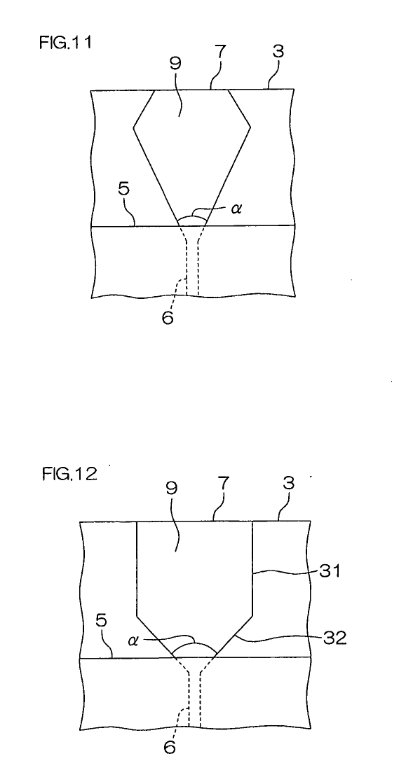

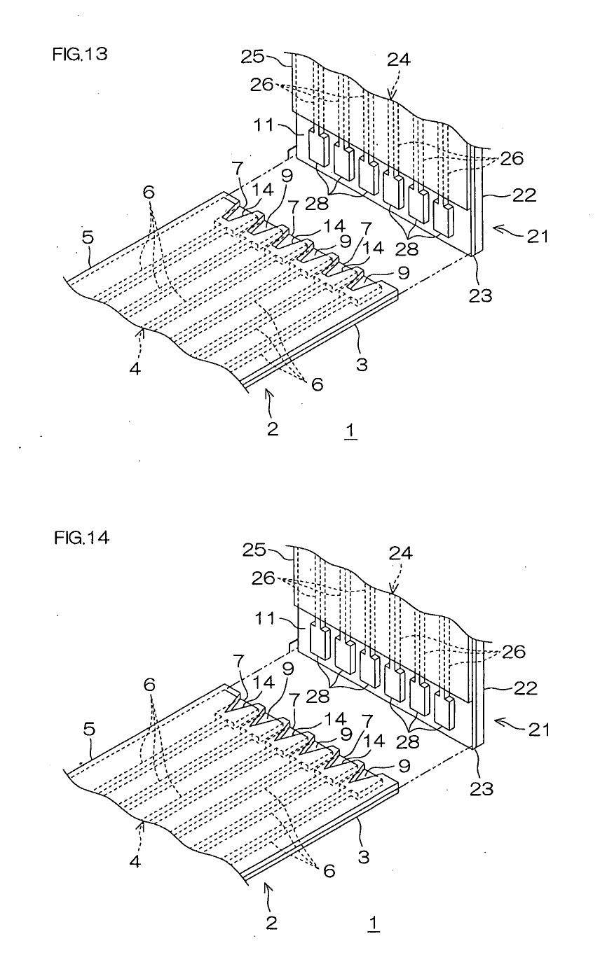

FIG. 9 is a perspective view of a suspension terminal as another embodiment (an embodiment formed in a generally trapezoidal shape having a generally right angle) of the wired circuit board according to the present invention; FIG. 10 is a perspective view of a suspension terminal as another embodiment (an embodiment formed in a generally trapezoidal shape with both widthwise opposite edges thereof being curved) of the wired circuit board according to the present invention; FIG. 11 is a perspective view of a suspension terminal as another embodiment (an embodiment formed in a generally hexagonal shape) of the wired circuit board according to the present invention; FIG. 12 is a perspective view of a suspension terminal as another embodiment (an embodiment formed in a generally hexagonal shape) of the wired circuit board according to the present invention; FIG. 13 is a perspective view of another embodiment (an embodiment in which a placement surface is exposed in a generally trapezoidal shape from a cutout) of the wired circuit board according to the present invention; and FIG. 14 is a perspective view of another embodiment (an embodiment in which a placement surface is exposed in a generally triangular shape from a cutout) of the wired circuit board according to the present invention.

The same reference numerals are provided in each of the subsequent figures for members corresponding to each of those described above, and their detailed description is omitted.

In the above explanation, the suspension terminal 7 is formed in a generally trapezoidal shape in plan view. However, the shape thereof is not particularly limited, and the suspension terminal 7 may be formed into, for example, a generally trapezoidal shape having a generally right angle as shown in FIG. 9; a generally trapezoidal shape with both widthwise opposite edges thereof being curved as shown in FIG. 10; or a generally hexagonal shape having a gravity center on the front side as shown in FIGS. 11 and 12.

In FIG. 9, at each of the suspension terminals 7, one widthwise edge thereof is parallel along the lengthwise direction, so that an angle formed between one widthwise edge and the leading edge thereof is a generally right angle.

The other widthwise edge of each of the suspension terminals 7 is inclined relative to one widthwise edge thereof so as to be gradually spaced away from one widthwise edge thereof toward the front side.

The angle β between the other widthwise edge and one widthwise edge is, for example, 20 degrees or more and less than 90 degrees, or preferably 40 degrees or more and less than 90 degrees.

In FIG. 10, each of the suspension terminals 7 is formed in a generally trapezoidal shape in plan view with both widthwise opposite edges thereof being curved outward.

In FIG. 11, the suspension terminal 7 is formed in a generally hexagonal shape obtained by cutting both widthwise ends of the front end portion of the suspension terminal 7 shown in FIG. 3 into a generally triangular shape.

More specifically, each of the suspension terminals 7 includes a front portion 31 having a generally trapezoidal shape in plan view narrowing toward the front side, and a rear portion 32 having a generally trapezoidal shape in plan view continuously formed on the rear side of the front portion 31.

The leading edge of the front portion 31 is arranged in the same position as the leading edge of the first insulating base layer 3. Both widthwise edges of the front portion 31 are formed so as to become closer to each other toward the front side.

The rear portion 32 is formed in a generally trapezoidal shape in plan view gradually widening toward the front side. Both widthwise edges of the rear portion 32 are formed so as to be gradually spaced away from each other toward the front side.

The length of the front portion 31 is formed shorter than that of the rear portion, so that the gravity center of each of the suspension terminals 7 exists on the front side.

The trailing edge of the rear portion 32 is covered with the leading edge of the first insulating cover layer 5.

The surface of the front portion 31, and the surfaces of the lengthwise center and the front end portion of the rear portion 32 serve as the placement surface 9. Since the trailing edge of the rear portion 32 is covered with the first insulating cover layer 5, the placement surface 9 in the rear portion 32 is formed in a generally trapezoidal shape gradually widening toward the front side.

In FIG. 12, each of the suspension terminals 7 includes a front portion 31 having a generally rectangular shape in plan view and a rear portion 32 having a generally rectangular shape in plan view continuously formed on the rear side of the front side 31.

In the above explanation, in the relay flexible wired circuit board 2, the leading edge of the first insulating cover layer 5 is linearly formed along the widthwise direction. However, for example, as shown in FIG. 13, it may be formed in a zigzag shape in plan view.

In FIG. 13, each of the suspension terminals 7 is formed in a generally rectangular shape (a square land) in plan view extending in the lengthwise direction. The width of each of the suspension terminals 7 and the spacing therebetween range, for example, from 20 to 800 μm, or preferably from 30 to 500 μm.

The leading edge of the first insulating cover layer 5 is formed in a sawtooth shape in plan view, and specifically, has cutouts 14 formed by cutting the first insulating cover layer 5 rearwardly corresponding to each of the suspension terminals 7.

Each of the cutouts 14 is formed in a generally trapezoidal shape in plan view gradually widening toward the front side. The size (size in plan view, i.e., length and spacing) of each cutout 14 is the same as that of the suspension terminal 7 shown in FIGS. 3 and 6 as described above.

In the first insulating cover layer 5, the leading edge other than the cutouts 14 is arranged in the same position as the leading edge of the first insulating base layer 3 as viewed in plane.

Thus, the cutouts 14 partially expose the placement surfaces 9 of the suspension terminals 7 in the above-mentioned generally trapezoidal shape in plan view.

In other words, the placement surfaces 9 of the suspension terminals 7 are exposed from the cutouts 14 of the first insulating cover layer 5 so as to be in a generally trapezoidal shape in plan view gradually widening toward the front side, and the surfaces (specifically, both edges of the rear end portion) other than the placement surfaces 9 in the suspension terminals 7 are covered with the first insulating cover layer 5.

Thus, the placement surfaces 9 are zoned by the cutouts 14 in the first insulating cover layer 5 so as to gradually widen toward the front side.

The first bumps 12 placed on the placement surfaces 9 serve as weirs by which the cutouts 14 in the first insulating cover layer 5 prevent the first bumps 12 from moving rearward during melting for connection between the suspension terminals 7 and the relay terminals 28. Therefore, the first bumps 12 can be more securely in contact with the second bumps 13 to achieve further secure connection between the suspension terminals 7 and the relay terminals 28.

In the above explanation, the placement surface 9 is zoned into a generally trapezoidal shape. However, for example, as shown in FIG. 14, the placement surface 9 may be zoned into a generally triangular shape in plan view.

In FIG. 14, each of the cutouts 14 in the first insulating cover layer 5 is formed in a generally triangular shape in plan view gradually widening toward the front side.

Thus, the placement surfaces 9 of the suspension terminals 7 are exposed from the cutouts 14 in the first insulating cover layer 5 so as to be in a generally trapezoidal shape in plan view gradually widening toward the front side.

Then, in the relay flexible wired circuit board 2 shown in FIG. 14, the placement surfaces 9 are compactly zoned as compared with the placement surfaces 9 in FIG. 13. Therefore, even if the amount of the material used for formation of the first bumps 12 is reduced, the first bumps 12 and the second bumps 13 can be in contact with each other. Thus, cost can be further reduced.

On the other hand, in the relay flexible wired circuit board 2 shown in FIG. 13, the placement surfaces 9 are widely zoned as compared with the placement surfaces 9 in FIG. 14. Therefore, even if the amount of the material used for the formation of the first bumps 12 is increased, the first bumps 12 can be securely in contact with the second bumps 13 while effectively preventing a short circuit between adjacent suspension terminals 7 in the widthwise direction. This can achieve secure connection between the suspension terminals 7 and the relay terminals 28.

While the illustrative embodiments of the present invention are provided in the above description, such is for illustrative purpose only and it is not to be construed limitative. Modification and variation of the present invention that will be obvious to those skilled in the art is to be covered by the following claims.

What is claimed is:

1. A wired circuit board comprising:
a first wired circuit board provided with a first conductive pattern which has a first terminal comprising a placement surface for placing a meltable metal and a first wire continuous with the first terminal; and
a second wired circuit board provided with a second conductive pattern which has a second terminal connected with the first terminal through the meltable metal and a second wire continuous with the second terminal,
wherein the first wired circuit board and the second wired circuit board are arranged so that a first plane containing the first terminal and a second plane containing the second terminal are intersected with each other, and
the placement surface is zoned so as to gradually widen toward the second terminal.

2. The wired circuit board according to claim 1,
wherein the first wired circuit board comprises an insulating cover layer which covers the first wire and exposes the first terminal, and
the first terminal is formed so as to gradually widen toward the second terminal, whereby the placement surface is zoned so as to gradually widen toward the second terminal.

3. The wired circuit board according to claim 1,
wherein the first wired circuit board comprises an insulating cover layer which covers the first wire and partially exposes the first terminal, and
the placement surface is zoned so as to gradually widen toward the second terminal, by being exposed from the insulating cover layer so as to gradually widen toward the second terminal.

4. The wired circuit board according to claim 1, wherein the placement surface is zoned in a generally trapezoidal shape when projected in a thickness direction of the first wired circuit board.

5. The wired circuit board according to claim 1, wherein the placement surface is zoned in a generally triangular shape when projected in a thickness direction of the first wired circuit board.

6. A connection structure of wired circuit boards, comprising:
a first wired circuit board provided with a first conductive pattern which has a first terminal comprising a placement surface for placing a meltable metal and a first wire continuous with the first terminal; and
a second wired circuit board provided with a second conductive pattern which has a second terminal connected with the first terminal through the meltable metal and a second wire continuous with the second terminal,
wherein the first wired circuit board and the second wired circuit board are arranged so that a first plane containing the first terminal and a second plane containing the second terminal are intersected with each other,
the placement surface is zoned so as to gradually widen toward the second terminal, and
the first terminal and the second terminal is connected through the meltable metal.

7. A method for connecting wired circuit boards comprising the steps of:
preparing a first wired circuit board provided with a first conductive pattern which has a first terminal comprising a placement surface zoned so as to gradually widen outward and a first wire continuous with the first terminal;
preparing a second wired circuit board provided with a second conductive pattern which has a second terminal and a second wire continuous with the second terminal;
placing a meltable metal on the placement surface of the first terminal;
arranging the first wired circuit hoard and the second wired circuit board so that a first plane comprising the first terminal and the second plane comprising the second terminal are intersected with each other; and
connecting the first terminal and the second terminal through the meltable metal by melting the meltable metal.
